(19) United States
(12) Patent Application Publication
(10) Pub. No.: US 2011/0222346 A1
(43) Pub. Date: Sep. 15, 2011

(54) NAND-TYPE FLASH MEMORY

(75) Inventor: Yasuhiko HONDA, Hiratsuka-shi (JP)

(73) Assignee: Kabushiki Kaisha Toshiba, Tokyo (JP)

(21) Appl. No.: 12/881,688

(22) Filed: Sep. 14, 2010

(30) Foreign Application Priority Data
Mar. 15, 2010 (JP) 2010-057642

(51) Int. Cl. G11C 16/04

(52) U.S. Cl. 365/185.17; 365/185.2

(57) ABSTRACT

A NAND-type flash memory has a bit line; a source line; and a NAND string that is configured by connecting a plurality of memory cells, into which data can be electrically rewritable, in series. The NAND-type flash memory has a drain-side selection gate transistor that has a gate to which a drain-side selection gate line is connected and that is connected between one end of the NAND string and the bit line; and a source-side selection gate transistor that has a gate to which a source-side selection gate line is connected and that is connected between the other end of the NAND string and the source line. The NAND-type flash memory has a row decoder that selects the memory cell by controlling voltages applied to control gates of the memory cells and that controls voltages applied to the drain-side selection gate line and the source-side selection gate line; and a bit line control circuit that controls a voltage of the bit line.

### CROSS-REFERENCE TO RELATED APPLICATION

This application is based upon and claims the benefit of priority from the prior Japanese Patent Application No.2010-57642, filed on Mar. 15, 2010, the entire contents of which are incorporated herein by reference.

### FIELD

Embodiments described herein relate generally to a NAND-type flash memory.

### BACKGROUND

Conventionally, in memory cell arrays of NAND-type flash memories, a NAND string is configured by a plurality of memory cells that are connected in series between two selection transistors.

In a write operation for these NAND-type flash memories, by utilizing coupling between the word line and the channel or the like, an electric potential difference between a word line and a channel is suppressed by raising the electric potential of the NAND string. Accordingly, non-selection of the NAND string is implemented.

Here, as the NAND-type flash memories are miniaturized, the threshold of the selection transistor connected to the NAND string remarkably changes between a case where the electric potential of adjacent NAND string is raised (that is; the adjacent NAND string is non-selected) and a case where the electric potential of adjacent NAND string is not raised (that is; the adjacent NAND string is selected). Accordingly, the width of the voltage of the bit line that can be set may be decreased.

Here, among conventional NAND-type flash memories, there is a NAND-type flash memory in which the electric potentials of the control gates of other memory cells positioned on both sides of a memory cell as a writing target are set to be low, and the electric potentials of the control gates of other memory cells are set to be further low (for example, see JP-A-2009-205728 (KOKAI)). Accordingly, erroneous writing for non-selected memory cells and a variation in the threshold thereof are prevented.

In addition, there is another conventional NAND-type flash memory in which control of the gate voltage of a selection transistor is assisted by setting the gate voltage of selection transistor adjacent to the selection transistor to an intermediate electric potential (for example, see JP-A-2006-302411 (KOKAI)).

However, the relationship of coupling between a selection transistor and a memory cell adjacent to this selection transistor is not mentioned in these general technologies.

### BRIEF DESCRIPTION OF THE DRAWINGS

FIG. 1 is a block diagram showing an example of the configuration of a NAND-type flash memory 100 according to a first embodiment;

FIG. 2 is a circuit diagram showing an example of the configuration according to the first embodiment that includes a memory cell array 1, a bit line control circuit 2, and a row decoder 6 shown in FIG. 1;

FIG. 3 is a cross-sectional view showing one memory cell of the memory cell array 1 shown in FIG. 2;

FIG. 4 is a cross-sectional view showing cross sections of the drain-side selection MOS transistor SGDTr, the source-side selection MOS transistor SGSTr of the memory cell array 1 shown in FIG. 2;

FIG. 5 is a diagram showing an example of operation waveforms in a write operation of the NAND-type flash memory shown in FIGS. 1 and 2;

FIG. 6 is a diagram showing the relationship between the defective rate of the memory cell and the voltage vsgd applied to the gate of the drain-side selection MOS transistor;

FIG. 7 is a cross-sectional view taken along a drain-side selection gate line SGD positioned near three adjacent drain-side selection MOS transistors SGDTr;

FIG. 8 is a diagram showing the configuration of three adjacent drain-side selection MOS transistors SGDTr and a part of NAND strings connected to the drain-side selection MOS transistors SGDTr according to the first embodiment;

FIG. 9 is a diagram showing the configuration of three adjacent drain-side selection MOS transistors SGDTr and a part of NAND strings connected to the drain-side selection MOS transistors SGDTr according to second embodiment;

FIG. 10 is a diagram showing the configuration of three adjacent drain-side selection MOS transistors SGDTr and a part of NAND strings connected to the drain-side selection MOS transistors SGDTr according to third embodiment; and

FIG. 11 is a diagram showing the configuration of three adjacent drain-side selection MOS transistors SGDTr and a part of NAND strings connected to the drain-side selection MOS transistors SGDTr according to the fourth embodiment.

### DETAILED DESCRIPTION

In general, according to one embodiment, A NAND-type flash memory includes a bit line; a source line; a NAND string; a drain-side selection gate transistor; a source-side selection gate transistor. The NAND string is configured by connecting a plurality of memory cells, into which data can be electrically rewritable, in series. The drain-side selection gate transistor that has a gate to which a drain-side selection gate line is connected and that is connected between one end of the NAND string and the bit line; the source-side selection gate transistor that has a gate to which a source-side selection gate line is connected and that is connected between the other end of the NAND string and the source line.

The NAND-type flash memory includes a row decoder; a bit line control circuit. The row decoder selects the memory cell by controlling voltages applied to control gates of the memory cells and controls voltages applied to the drain-side selection gate line and the source-side selection gate line. The bit line control circuit controls a voltage of the bit line. The row decoder applies a first voltage to the control gate of a first memory cell, which is adjacent to the drain-side selection gate transistor, of the NAND string in a write operation, the first voltage being set lower than that applied to the control gates of other memory cells so as to cut off the other memory cells of the NAND string from the drain-side selection gate transistor.

Embodiments will now be explained with reference to the accompanying drawings.

### First Embodiment

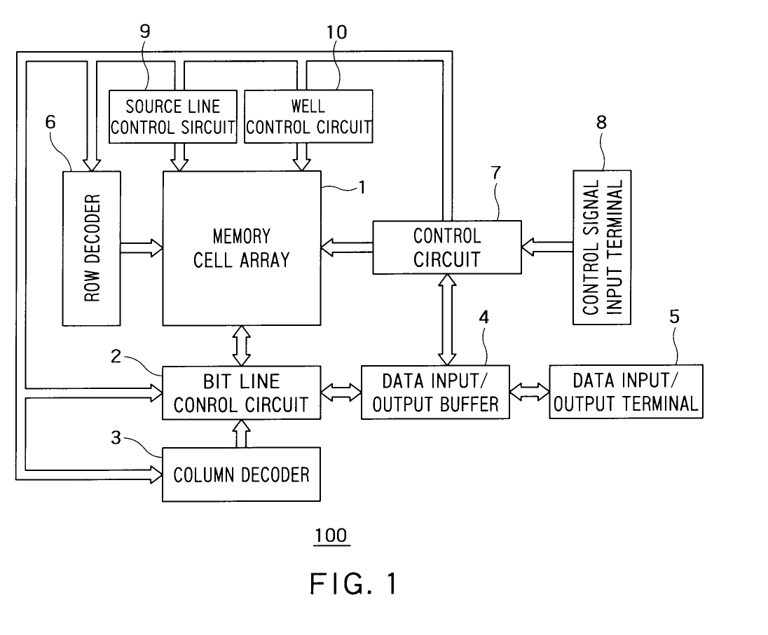

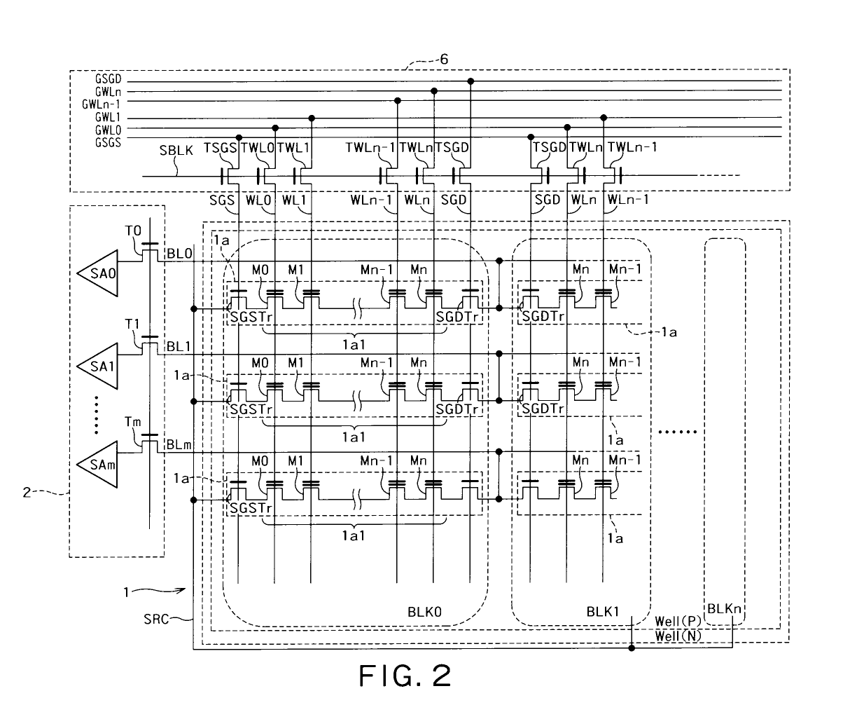

FIG. 1 is a block diagram showing an example of the configuration of a NAND-type flash memory 100 according to a first embodiment. FIG. 2 is a circuit diagram showing an example of the configuration according to the first embodiment that includes a memory cell array 1, a bit line control circuit 2, and a row decoder 6 shown in FIG. 1.

As shown in FIG. 1, the NAND-type flash memory 100 includes a memory cell array 1, a bit line control circuit 2, a column decoder 3, a data input/output buffer 4, a data input/output terminal 5, a row decoder 6, a control circuit 7, a control signal input terminal 8, a source line control circuit 9, and a well control circuit 10.

The memory cell array 1 includes a plurality of bit lines, a plurality of word lines, and a source line. This memory cell array 1 includes a plurality of blocks (BLK0 to BLKn in FIG. 2) in which memory cells, into which data is electrically rewritable, formed from EEPROM cells are disposed in a matrix pattern.

The bit line control circuit 2 used for controlling the voltages of bit lines and the row decoder 6 used for controlling the voltages of the word lines are connected to this memory cell array 1. In a write operation of data, one block is selected by the row decoder 6, and the other blocks are in a non-selection state.

The bit line control circuit 2 includes a plurality of sense amplifiers SA (FIG. 2) that sense and amplify the voltages of bit lines 1, MOS transistors (FIG. 2) each connected between the bit line and the sense amplifier SA, and data storage circuits (not shown) that also have the function of a data latch circuit used for latching data to be written.

This bit line control circuit 2 reads data of a memory cell of the memory cell array 1 through the bit line, detects the status of the memory cell through the bit line, or writes data into the memory cell by applying a write control voltage to the memory cell through the bit line.

In addition, the bit line control circuit 2, the column decoder 3 and the data input/output buffer 4 are connected. The data storage circuit disposed inside the bit line control circuit 2 is selected by the column decoder 3, and the data of the memory cell that is read out by the data storage circuit is output to the outside thereof from the data input/output terminal 5 through the data input/output buffer 4.

In addition, write data input from the outside to the data input/output terminal 5 is stored in the data storage circuit that is selected by the column decoder 3 through the data input/output buffer 4. From the data input/output terminal 5, various commands such as a write, a read, an erase, and a status read and an address other than the write data are also input.

The row decoder 6 is connected to the memory cell array 1. This row decoder 6 applies a voltage that is necessary for read, write, or erase to a word line of the memory cell array 1.

The source line control circuit 9 is connected to the memory cell array 1. This source line control circuit 9 is configured so as to control the voltage of the source line SRC.

The well control circuit 10 is connected to the memory cell array 1. This well control circuit 10 is configured so as to control the voltage of a semiconductor substrate (well) in which the memory cells are formed.

The control circuit 7 is configured so as to control the memory cell array 1, the bit line control circuit 2, the column decoder 3, the data input/output buffer 4, the row decoder 6, the source line control circuit 9, and the well control circuit 10. That is, the control circuit 7 has a function of generally controlling the overall operation of the NAND-type flash memory 100.

Here, a voltage booster circuit (not shown) that raises the voltage of a power source voltage is assumed to be included in the control circuit 7. The control circuit 7 is configured so as to raise the voltage of the power source voltage as necessary by using the voltage booster circuit and supply a resultant voltage to the bit line control circuit 2, the column decoder 3, the data input/output buffer 4, the row decoder 6, the source line control circuit 9, and the well control circuit 10.

This control circuit 7 controls operation according to control signals (a command latch enable signal CLE, an address latch enable signal ALE, a ready/busy signal RY/BY, or the like) that are input from the outside through the control signal input terminal 8 and a command that is input from the data input/output terminal 5 through the data input/output buffer 4. In other words, when data is programmed, verified, read, and erased according to the control signals and the command, the control circuit 7 generates a desired voltage and supplies the resultant voltage to each portion of the memory cell array 1.

Here, as shown in FIG. 2, the memory cell array 1 has blocks BLK0 to BLKn each configured by connecting a plurality of NAND cell units 1a. The blocks BLK0 to BLKn are formed in a p well Well(p) that is formed in an n well Well(n) of the semiconductor substrate.

The NAND cell unit 1a is configured by a plurality of (n+1 (for example, 64)) memory cells M0 to Mn, which are connected in series, configuring a NAND string, a drain-side selection MOS transistor SGDTr, and a source-side selection MOS transistor SGSTr. In addition, the drain-side selection MOS transistor SGDTr is connected to the bit line and the source-side selection MOS transistor SGSTr is connected to the source line SRC. Here, the source-side selection gate transistor SGSTr and the drain-side selection gate transistor SGDTr are n-type MOS transistors.

A control gate of the memory cells M0 to Mn disposed in each row is connected to the word lines WL0 to WLn.

The bit lines BL0 to BLm are disposed so as to run perpendicular to the word lines WL0 to WLn and the source line SRC.

In addition, the gate of the drain-side selection MOS transistor SGDTr is connected to a drain-side selection gate line SGD. The drain-side selection gate transistor SGDTr is connected between one end of the NAND string 1a1 and the respective bit lines BL0 to BLm.

In addition, the gate of the source-side selection MOS transistor SGSTr is connected to a source-side selection gate line SGS. The source-side selection gate transistor SGSTr is connected between the other end of the NAND string 1a1 and the source line SRC.

In addition, (m+1) sense amplifiers SA0 to SAm in the bit line control circuit 2 are connected to respective bit lines BL0 to BLm through MOS transistors T0 to Tm. Furthermore, the sense amplifiers SA0 to SAm are configured so as to sense or control the electric potentials of the connected bit lines BL0 to BLm

As shown in FIG. 2, the row decoder 6 has a plurality of control lines GSGS, GSGD, WL0 to WLn, and SBLK and a plurality of transfer MOS transistors TSGS, TSGDE, and TWL0 to TWLn that are n-type MOS transistors.

The drains of the transfer MOS transistors TSGS and TSGD are connected to the source-side selection gate line SGS and the drain-side selection gate line SGD respectively. The drains of the transfer MOS transistors TWL0 to TWLn are connected to the word lines WL0 to WLn that are connected to the control gate of the memory cells M0 to Mn.

The sources of these transfer MOS transistors TSGS, TSGD, and TWL0 to TWLn are connected to the control lines GSGS, GSGD, GWL0 to GWLn.

In addition, the gate voltages and the source voltages of the transfer MOS transistors TSGS, TSGD, and TWL0 to TWLn are controlled by a driver circuit (not shown) according to the output of the control circuit 7. For example, to the gates of the transfer MOS transistors TSGS, TSGDE, TSGDO, and TWL0 to TWLx, block selection signals are input according to an address input to the driver circuit from an internal address line not shown in the figure.

In other words, the row decoder 6 controls the transfer MOS transistors TSGS, TSGD, and TWL0 to TWLn by controlling the gate voltages and the source voltages by using the driver circuit.

Accordingly, each block BLK0 to BLKn of the memory cell array 1 is selected, and a write operation or a read operation for the selected block is controlled. In other words, the row decoder 6 selects the memory cell by controlling the voltages applied to the drain-side selection gate line and the source-side selection gate line and controlling the voltages applied to the word lines (control gates of the memory cells).

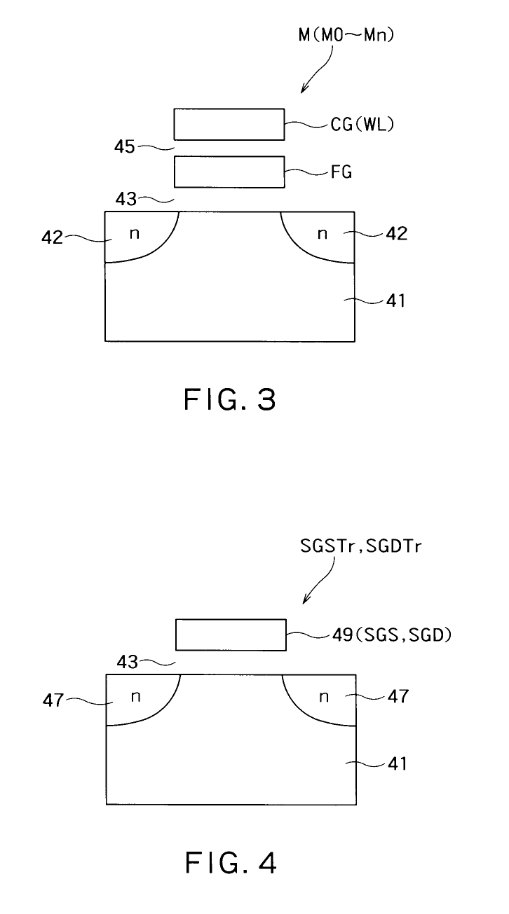

Here, FIG. 3 is a cross-sectional view showing one memory cell of the memory cell array 1 shown in FIG. 2.

As shown in FIG. 3, the memory cell M (M0 to Mn) has a charge accumulation layer (for example, a floating gate FG), a control gate CG, and a diffusion layer 42. The control gate CG is electrically connected to the word line WL and is common to the plurality of the memory cells M0 to Mn.

In a well (here, a p well) 41 formed in the semiconductor substrate, a diffusion layer 42 that becomes a source-drain diffusion layer (here, an n+ diffusion layer) of the memory cell M is formed. In addition, a floating gate FG is formed on the well 41 with a gate insulating film (tunnel insulating layer) 43 interposed therebetween. A control gate CG is formed on the floating gate FG with a gate insulating film 45 interposed therebetween.

This memory cell M is configured such that data is stored therein according to a threshold voltage and the stored data can be electrically rewritten by controlling the threshold voltage. The threshold voltage is determined based on the amount of electric charges that can be accumulated in the floating gate FG. The amount of electric charges accumulated in the floating gate FG can be changed according to a tunnel current passing through a gate insulating film 43.

In other words, when the control gate CG is maintained at a voltage that is sufficiently high with respect to the well 41 and the diffusion layer (the source diffusion layer/the drain diffusion layer) 42, electrons are injected into the floating gate FG through the gate insulating film 43. Accordingly, the threshold voltage of the memory cell M becomes higher (for example, it corresponds to a write state when the stored data is binary).

On the other hand, when the well 41 and the diffusion layer (the source diffusion layer/the drain diffusion layer) 42 are maintained at a voltage that is sufficiently high with respect to the control gate CG, electrons are discharged from the floating gate FG through the gate insulating film 43. Accordingly, the threshold voltage of the memory cell M becomes lower (for example, it corresponds to an erase state when the stored data is binary).

As described above, the memory cell M can rewrite the stored data by controlling the amount of electric charges accumulated in the floating gate FG.

FIG. 4 is a cross-sectional view showing cross sections of the drain-side selection MOS transistor SGDTr, the source-side selection MOS transistor SGSTr of the memory cell array 1 shown in FIG. 2.

As shown in FIG. 4, in the well 41, a diffusion layer 47 that becomes a source diffusion layer/drain diffusion layer of the drain-side selection MOS transistor SGDTr and the source-side selection MOS transistor SGSTr is formed. On the well 41, a control gate 49 (SGS and SGD) is formed on the well 41 with a gate insulating film (tunnel insulating layer) 43 interposed therebetween.

Next, an example of the operation of the NAND-type flash memory 100 having the above configuration will be described.

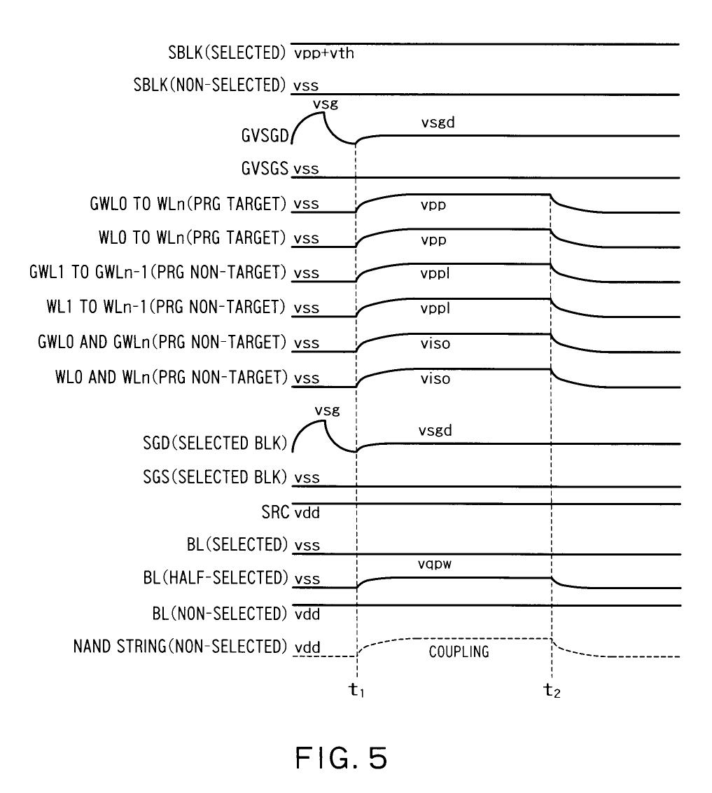

FIG. 5 is a diagram showing an example of operation waveforms in a write operation of the NAND-type flash memory shown in FIGS. 1 and 2.

As shown in FIG. 5, in the write operation, first, the voltage of the control line SBLK is set to a sum of a voltage vpp and the threshold voltage Vth of the transfer MOS transistor for a selected block of a writing target. Accordingly, the transfer MOS transistor is turned on. In such a case, the voltages of the control lines GSGS, GSGD, and GWL0 to GWLn are transferred to the source-side selection gate line SGS, the drain-side selection gate line SGD, and the word lines WL0 TO WLn by the transfer MOS transistor.

On the other hand, the voltage of the control line SBLK is set to the ground voltage vss for a non-selected block of a non-writing target. Accordingly, the transfer MOS transistor is tuned off. In other words, the voltages of the control lines GSGS, GSGD, and GWL0 to GWLn are not transferred. Accordingly, hereinafter, the description will be focused on a selected block.

Here, the voltage of the control line GSGS is set to the ground voltage vss, and the voltage of the control line GSGD is raised up to a voltage Vsg and then is dropped. Accordingly, the voltage of the source-side selection gate line SGS is set to the ground voltage vss, and the voltage of the drain-side selection gate line SGD is raised up to the voltage Vsg and then is dropped.

Next, at time t1, the voltage of the drain-side selection gate line SGD is raised up to a voltage Vsgd.

In addition, the voltage of a bit line that is selected (hereinafter, also referred to as a selected bit line) BL is set to the ground voltage vss, the voltage of a bit line that is half-selected (hereinafter, also referred to as a half-selected bit line) BL is set to a voltage vqpw that is higher than the ground voltage vss, and the voltage of a bit line that is not selected (hereinafter, also referred to as a non-selected bit line) BL is set to the power source voltage vdd.

In addition, the voltage of the half-selected bit line is set higher than that of the selected bit line, so that the writing speed for a memory cell connected to the half-selected bit line decreases.

As described above, the voltage vqpw is equal to or higher than the ground voltage vss and lower than the power source voltage vdd. The voltage of the word line WL of a writing target is set to the voltage vpp having a high electric potential, and the voltage of the word line WL of a non-writing target is set to a voltage vppl that is lower than the voltage vpp.

In addition, as the voltage of one of the control lines (PRG target) GWL0 to GWLn of writing targets is raised up to the voltage vpp, the voltage of one of the words lines (PRG target) WL0 to WLn that are connected to the memory cells of the writing targets is raised up to the voltage vpp. Here, the remaining control lines and the remaining word lines correspond to control lines (non PRG targets) and word lines (non PRG targets) of non-writing targets to be described below.

Accordingly, the threshold voltage of the memory cell that is selected by the word line of the writing target and the selected bit line changes as electrons are injected into the charge accumulation layer (a floating gate) of the memory cell according to an electric potential difference between the voltage vpp and the ground voltage vss. In other words, data is written into the selected memory cell (times t1 to t2).

In addition, for the half-selected bit line, there is an electric potential difference between the voltage vpp and the voltage vqpw, and accordingly, a write operation is performed for the memory cell that is half-selected by the half-selected bit line and the word line of the writing target, but the writing speed is low, and the amount of writing (the amount of injection of electric charges) is small. By performing a write operation for the memory cell that has a threshold voltage near a target write level in the half-selected state, data is prevented from being written into the memory cell too much.

On the other hand, as the voltages of the control lines (non PRG targets) GWL1 to GWLn−1 of the non-writing targets are raised up to the voltage vppl, the voltages of the word lines (non PRG targets) WL1 to WLn−1 connected to the memory cells of the non-writing targets rise up to the voltage vppl.

In addition, as the voltages of the control lines (non PRG targets) GWL0 and GWLn of the non-writing targets are raised up to a voltage viso, the voltages of the word lines (non PRG targets) WL0 to WLn connected to the memory cells of the non-writing targets rise only up to a voltage viso that is close to the ground voltage vss.

As described above, in the write operation, to the control gate of the memory cell Mn, which is adjacent to the drain-side selection gate transistor SGDTr, of the NAND string 1a1, the row decoder 6 applies the voltage viso that is set lower than that applied to the control gates of the other memory cells M1 to Mn−1 of the NAND string 1a1 so as to cut off the other memory cells M1 to Mn−1 of the NAND string 1a1 from the drain-side selection gate transistor SGDTr.

Likewise, in the write operation, to the control gate of the memory cell M0, which is adjacent to the source-side selection gate transistor SGSTr, of the NAND string 1a1, the row decoder 6 applies the voltage viso that is set lower than that applied to the control gates of the other memory cells M1 to Mn−1 so as to cut off the other memory cells M1 to Mn−1 of the NAND string 1a1 from the source-side selection gate transistor SGSTr.

In other words, the memory cells M0 and Mn, which are adjacent to the selection MOS transistors SGSTr and SGDTr, cut off the memory cells M1 to Mn−1 from the selection MOS transistors SGSTr and SGDTr. Accordingly, it can be suppressed that the voltage of the channel of the NAND string propagates to the side of the selection MOS transistors SGSTr and SGDTr.

In addition, the NAND string (non-selected) of the non-writing target is a floating state due to being coupled with the word line. Accordingly, the electric potential difference between the memory cells configuring this NAND string is alleviated, and thus data is not written into the NAND string of the non-writing target (times t1 to t2).

Here, as described above, in order not to allow the voltage of the channel of the NAND string of the non-writing target to leak to the bit line, the gate voltage of the drain-side selection MOS transistor SGDTr positioned on the drain side is set to a voltage vsgd, and the drain-side selection MOS transistor SGDTr is cut off. In addition, simultaneously, the selected bit line BL (the ground voltage vss) and the non-selected bit line BL (vqpw) need to be connected to the NAND string of the writing target. Accordingly, basically, the voltage vsgd needs to be set in the range shown in Equation (1).

Vqpw+vthn≦vsgd≦vdd+vthn (1)

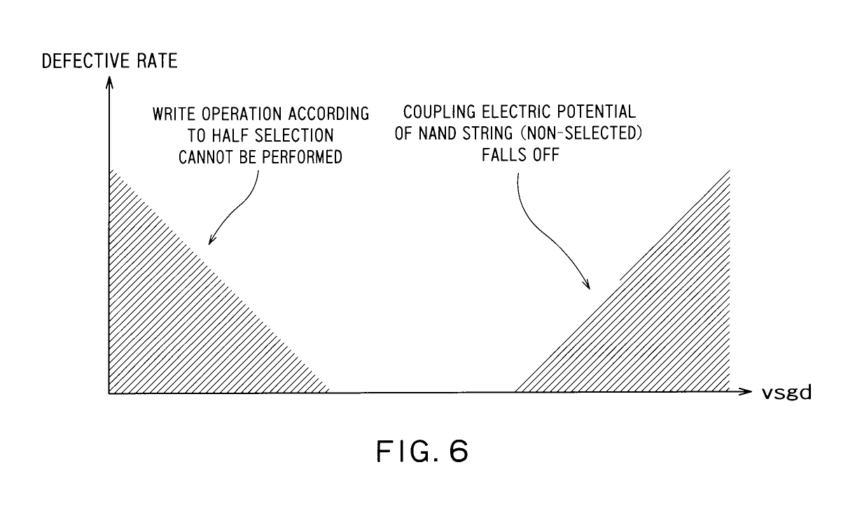

Here, FIG. 6 is a diagram showing the relationship between the defective rate of the memory cell and the voltage vsgd applied to the gate of the drain-side selection MOS transistor.

Actually, as shown in FIG. 6, the value of the voltage vsgd is set by measuring the defective rate of the memory cell for the voltage vsgd in consideration of a range in which a write operation cannot be performed by half selection and a range in which the coupling electric potential of the NAND string (non-selected) falls off the bit line.

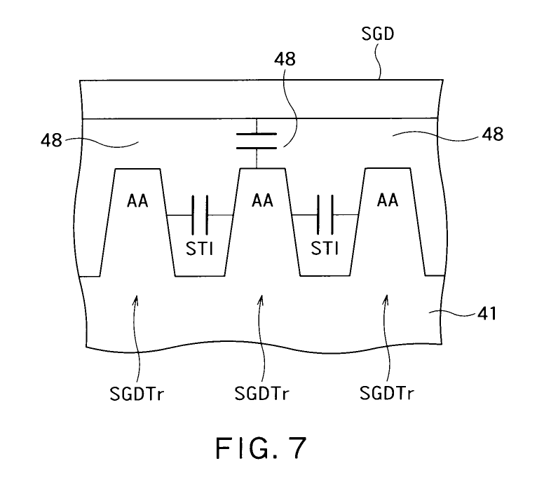

FIG. 7 is a cross-sectional view taken along a drain-side selection gate line SGD positioned near three adjacent drain-side selection MOS transistors SGDTr.

In the above Equation (1), a threshold voltage vthn of the drain-side selection MOS transistor SGDTr is included. As shown in FIG. 7, an element area AA of a drain-side selection MOS transistor SGDTr is adjacent to that of another adjacent drain-side selection MOS transistor SGDTr across an element separation film STI. Accordingly, coupling occurs between the drain-side selection MOS transistor SGDTr and another NAND string that is adjacent to a NAND string to which the drain-side selection MOS transistor SGDTr is connected.

Whether the channel of another adjacent NAND string has an increased voltage (non-selected) or is discharged (selected) influences the threshold voltage Vthn of the drain-side selection MOS transistor SGDTr.

As described above, recently, as the NAND-type flash memory is miniaturized, this influence becomes more remarkable.

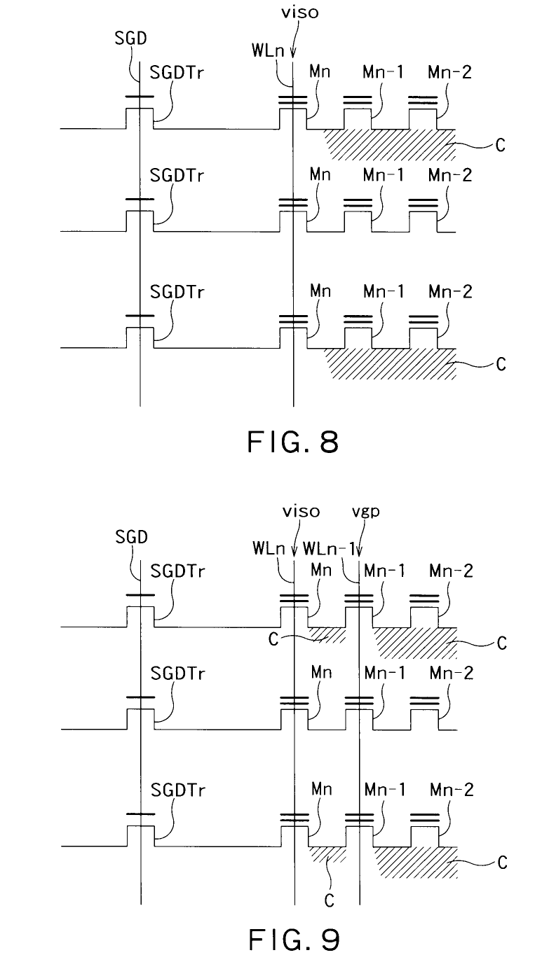

FIG. 8 is a diagram showing the configuration of three adjacent drain-side selection MOS transistors SGDTr and a part of NAND strings connected to the drain-side selection MOS transistors SGDTr according to the first embodiment.

In this embodiment, as shown in FIG. 8, as described above, the ground voltage vss or the voltage viso that is a voltage close thereto, instead of the voltage vppl, is applied to a word line WLn that is connected to the control gate of a memory cell Mn adjacent to the drain-side selection MOS transistor SGDTr positioned on the drain side. In other words, the memory cell Mn adjacent to the drain-side selection MOS transistor SGDTr cuts off the memory cells M1 to Mn−1 from the drain-side selection MOS transistor SGDTr.

Accordingly, the electric potential of the channel C of the NAND string that has a voltage raised due to coupling in the write operation is prevented from propagating up to the side of the drain-side selection MOS transistor SGDTr. Therefore, a variation in the threshold of the drain-side selection MOS transistor SGDTr caused by the coupling shown in FIG. 7 described above can be suppressed.

In addition, as described above, the same effect can be acquired for the source-side MOS transistor SGSTr by cutting off the memory cells M1 to Mn−1 from the source-side selection MOS transistor SGSTr by using the memory cell M0.

As described above, according to the NAND-type flash memory, the variation in the threshold of the selection transistor can be suppressed in a write operation of the NAND-type flash memory.

### Second Embodiment

In the above-described first embodiment, the electric potential differences of drain-to-gate/drain-to-source of the memory cells M0 and Mn adjacent to the selection MOS transistor are large.

Accordingly, electrons are generated due to a GIDL (Gate Inducted Drain Leakage) current, punch-through, or the like. These electrons may be injected into the memory cells M0 and Mn, whereby degrading the reliability.

Thus, in this second embodiment, the voltages of the control gates of the memory cells M1 and Mn−1 adjacent to the memory cells M0 and Mn are controlled to be regulated voltages so as to decrease the electric potentials applied to the memory cells M0 and Mn.

Hereinafter, an area that is adjacent to the drain-side selection MOS transistor will be described as an example. However, the same description can be similarly applied to an area that is adjacent to the source-side selection gate transistor. The general configuration of a NAND-type flash memory according to second embodiment is the same as that of first embodiment that is shown in FIG. 1. In addition, the configuration of the memory cell array 1 is the same as that of first embodiment that is shown in FIG. 2.

FIG. 9 is a diagram showing the configuration of three adjacent drain-side selection MOS transistors SGDTr and a part of NAND strings connected to the drain-side selection MOS transistors SGDTr according to second embodiment.

As shown in FIG. 9, in a write operation, a row decoder 6 applies a voltage vgp to the control gate (word line WLn) of a memory cell Mn−1, which is adjacent to a memory cell Mn, of the NAND string 1a1.

This voltage vgp is set lower than voltages vppl and vpp applied to the control gates of memory cells M2 to Mn−2 except for the memory cell Mn that is adjacent to the memory cell Mn−1 and higher than the voltage viso applied to the control gate of the memory cell Mn (Equation (2)).

Accordingly, the electric potential difference of drain-to-gate/drain-to-source of the memory cell Mn is decreased. Therefore, the GIDL current or the punch-through described above can be suppressed.

viso<vgp<vppl (2)

Similarly to the first embodiment, the ground voltage vss or the voltage viso that is a voltage close thereto, instead of the voltage vppl, is applied to a word line WLn that is connected to the control gate of a memory cell Mn adjacent to the drain-side selection MOS transistor SGDTr positioned on the drain side. In other words, the memory cell Mn adjacent to the drain-side selection MOS transistor SGDTr cuts off the memory cells M1 to Mn−1 from the drain-side selection MOS transistor SGDTr.

Accordingly, the electric potential of the channel C of the NAND string that has a voltage raised due to coupling in the write operation is prevented from propagating up to the side of the drain-side selection MOS transistor SGDTr. Therefore, a variation in the threshold of the drain-side selection MOS transistor SGDTr caused by the coupling shown in FIG. 7 described above can be suppressed.

In addition, as described above, the same effect can be acquired for a source-side selection MOS transistor SGSTr by cutting off the memory cells M1 to Mn−1 from the source-side selection MOS transistor SGSTr by using the memory cell M0.

As described above, according to the NAND-type flash memory, the variation in the threshold of the selection transistor can be suppressed in a write operation of the NAND-type flash memory.

### Third Embodiment

According to the first embodiment, when data is written into the memory cells M1 and Mn, the electric potential of the NAND string cannot be prevented from propagating up to the side of the drain-side selection MOS transistor SGDTr.

Thus, in a third embodiment, a case where a dummy memory cell row is disposed in a memory cell array 1, and propagation of the voltage of the channel of the NAND string is suppressed by applying a voltage viso to the control gate of the dummy cell will be described.

Hereinafter, an area that is adjacent to the drain-side selection MOS transistor will be described as an example. However, the same description can be similarly applied to an area that is adjacent to the source-side selection gate transistor.

The general configuration of a NAND-type flash memory according to the third embodiment is the same as that of the first embodiment that is shown in FIG. 1. In addition, the configuration of the memory cell array 1 is the same as that of the first embodiment shown in FIG. 2 except that a dummy memory cell and a word line and a control line, which are connected to this dummy memory cell, are added.

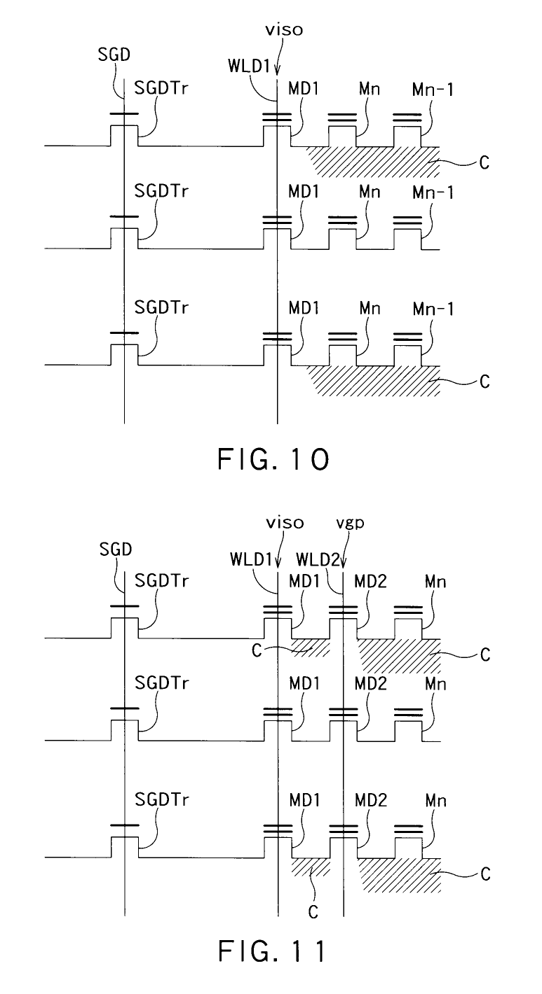

FIG. 10 is a diagram showing the configuration of three adjacent drain-side selection MOS transistors SGDTr and a part of NAND strings connected to the drain-side selection MOS transistors SGDTr according to third embodiment.

As shown in FIG. 10, the dummy memory cell MD1 is connected between the drain-side selection MOS transistor SGDTr and a memory cell Mn. This dummy memory cell MD1 has the same configuration as that of the memory cells M0 to Mn. To the control gate of the dummy memory cell MD1, a word line WLD1 that is connected to a row decoder 6 and has a controlled voltage is connected. This dummy memory cell MD1 is regulated in advance such that predetermined data (for example, user data input from the outside of the NAND-type flash memory 100) does not become a writing target.

Similarly to the first embodiment, in a write operation, to the word line WLD1 connected to the control gate of the dummy memory cell MD1 that is adjacent to the drain-side selection MOS transistor SGDTr, the ground voltage vss or a voltage viso that is a voltage close thereto is applied. In other words, the dummy memory cell MD1 adjacent to the drain-side selection MOS transistor SGDTr cuts off the memory cells M0 to Mn from the drain-side selection MOS transistor SGDTr.

Accordingly, the electric potential of the channel C of the NAND string that has a voltage raised due to coupling in the write operation is prevented from propagating up to the side of the drain-side selection MOS transistor SGDTr. Therefore, a variation in the threshold of the drain-side selection MOS transistor SGDTr caused by the coupling shown in FIG. 7 described above can be suppressed.

In addition, as described above, the same effect can be acquired for a source-side selection MOS transistor SGSTr by cutting off the memory cells M0 to Mn from the source-side selection MOS transistor SGSTr by using the dummy memory cell.

As described above, according to the NAND-type flash memory, the variation in the threshold of the selection transistor can be suppressed in a write operation of the NAND-type flash memory.

### Fourth Embodiment

In the above-described third embodiment, the electric potential difference of drain-to-gate/drain-to-source of the dummy memory cell adjacent to the selection MOS transistor is large. Accordingly, electrons are generated due to a GIDL current, punch-through, or the like.

Thus, in a fourth embodiment, a dummy memory cell that is adjacent to the dummy memory cell is further disposed, and the voltage of the control gate of this dummy memory cell is controlled to be a regulated voltage. Accordingly, the electric potential difference applied to the dummy memory cell adjacent to the selection MOS transistor is decreased.

Hereinafter, an area that is adjacent to the drain-side selection MOS transistor will be described as an example. However, the same description can be similarly applied to an area that is adjacent to the source-side selection gate transistor. The general configuration of a NAND-type flash memory according to the fourth embodiment is the same as that of the first embodiment that is shown in FIG. 1. In addition, the configuration of the memory cell array 1 is the same as that of the first embodiment shown in FIG. 2 except that a dummy memory cell and a word line and a control line, which are connected to this dummy memory cell, are added.

FIG. 11 is a diagram showing the configuration of three adjacent drain-side selection MOS transistors SGDTr and a part of NAND strings connected to the drain-side selection MOS transistors SGDTr according to the fourth embodiment.

As shown in FIG. 11, dummy memory cells MD1 and MD2 are connected in series between the drain-side selection MOS transistor SGDTr and a memory cell Mn. These dummy memory cells MD1 and MD2 have the same configuration as that of the memory cells M0 to Mn. To the control gates of the dummy memory cell MD1 and MD2, word lines WLD1 and WLD2 that are connected to a row decoder 6 and has controlled voltages are connected. These dummy memory cells MD1 and MD2 are regulated in advance such that predetermined data does not become a writing target.

As shown in FIG. 11, in a write operation, a row decoder 6 applies the voltage vgp shown in the above-described Equation (2) to the control gate (word line WLD2) of a dummy memory cell MD2, which is adjacent to a memory cell Mn, of the NAND string 1a1.

Accordingly, the electric potential difference of drain-to-gate/drain-to-source of the dummy memory cell MD1 is decreased. Therefore, the GIDL current or the punch-through described above can be suppressed.

Similarly to the first embodiment, the ground voltage vss or a voltage viso that is a voltage close thereto is applied to a word line WLD1 that is connected to the control gate of the dummy memory cell MD1 adjacent to the drain-side selection MOS transistor SGDTr positioned on the drain side. In other words, the memory cell Mn adjacent to the drain-side selection MOS transistor SGDTr cuts off the memory cells M1 to Mn−1 from the drain-side selection MOS transistor SGDTr.

Accordingly, the electric potential of the channel C of the NAND string that has a voltage raised due to coupling in the write operation is prevented from propagating up to the side of the drain-side selection MOS transistor SGDTr. Therefore, a variation in the threshold of the drain-side selection MOS transistor SGDTr caused by the coupling shown in FIG. 7 described above can be suppressed.

In addition, as described above, the same effect can be acquired for a source-side selection MOS transistor SGSTr by cutting off the memory cells from the source-side selection MOS transistor SGSTr by using the dummy memory cell MD1.

As described above, according to the NAND-type flash memory, the variation in the threshold of the selection transistor can be suppressed in a write operation of the NAND-type flash memory.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A NAND-type flash memory comprising:
a bit line;
a source line;
a NAND string that is configured by connecting a plurality of memory cells, into which data can be electrically rewritable, in series;
a drain-side selection gate transistor that has a gate to which a drain-side selection gate line is connected and that is connected between one end of the NAND string and the bit line;
a source-side selection gate transistor that has a gate to which a source-side selection gate line is connected and that is connected between the other end of the NAND string and the source line;
a row decoder that selects the memory cell by controlling voltages applied to control gates of the memory cells and that controls voltages applied to the drain-side selection gate line and the source-side selection gate line; and
a bit line control circuit that controls a voltage of the bit line,
wherein the row decoder applies a first voltage to the control gate of a first memory cell, which is adjacent to the drain-side selection gate transistor, of the NAND string in a write operation, the first voltage being set lower than that applied to the control gates of other memory cells so as to cut off the other memory cells of the NAND string from the drain-side selection gate transistor.

2. The NAND-type flash memory according to claim 1, wherein the row decoder applies a second voltage to the control gate of a second memory cell, which is adjacent to the first memory cell, of the NAND string in the write operation, the second voltage being set lower than a third voltage applied to the control gate of a third memory cell other than the first memory cell, which is adjacent to the second memory cell, of the NAND string, and the second voltage being set higher than the first voltage.

3. The NAND-type flash memory according to claim 1, wherein the first memory cell is a dummy memory cell being regulated in advance such that predetermined data does not become a writing target.

4. The NAND-type flash memory according to claim 2, wherein the first memory cell and the second memory cell are dummy memory cells being regulated in advance such that predetermined data does not become a writing target.

5. The NAND-type flash memory according to claim 2, wherein the first voltage is a ground voltage.

6. The NAND-type flash memory according to claim 2, wherein the source-side selection gate transistor and the drain-side selection gate transistor are nMOS transistors.

7. The NAND-type flash memory according to claim 4, wherein the source-side selection gate transistor and the drain-side selection gate transistor are nMOS transistors.

8. A NAND-type flash memory comprising:
a bit line;
a source line;
a NAND string that is configured by connecting a plurality of memory cells, into which data can be electrically rewritable, in series;
a drain-side selection gate transistor that has a gate to which a drain-side selection gate line is connected and that is connected between one end of the NAND string and the bit line;
a source-side selection gate transistor that has a gate to which a source-side selection gate line is connected and that is connected between the other end of the NAND string and the source line;
a row decoder that selects the memory cell by controlling voltages applied to control gates of the memory cells and that controls voltages applied to the drain-side selection gate line and the source-side selection gate line; and
a bit line control circuit that controls a voltage of the bit line,
wherein the row decoder applies a first voltage to the control gate of a first memory cell, which is adjacent to the source-side selection gate transistor, of the NAND string in a write operation, the first voltage being set lower than that applied to the control gates of other memory cells so as to cut off the other memory cells of the NAND string from the source-side selection gate transistor.

9. The NAND-type flash memory according to claim 8, wherein the row decoder applies a second voltage to the control gate of a second memory cell, which is adjacent to the first memory cell, of the NAND string in the write operation, the second voltage being set lower than a third voltage applied to the control gate of a third memory cell other than the first memory cell, which is adjacent to the second memory cell, of the NAND string, and the second voltage being set higher than the first voltage.

10. The NAND-type flash memory according to claim 8, wherein the first memory cell is a dummy memory cell being regulated in advance such that predetermined data does not become a writing target.

11. The NAND-type flash memory according to claim 9, wherein the first memory cell and the second memory cell are dummy memory cells being regulated in advance such that predetermined data does not become a writing target.

12. The NAND-type flash memory according to claim 9, wherein the first voltage is a ground voltage.

13. The NAND-type flash memory according to claim 9, wherein the source-side selection gate transistor and the drain-side selection gate transistor are nMOS transistors.

14. The NAND-type flash memory according to claim 11, wherein the source-side selection gate transistor and the drain-side selection gate transistor are nMOS transistors.

15. A NAND-type flash memory comprising:
a bit line;
a source line;
a NAND string that is configured by connecting a plurality of memory cells, into which data can be electrically rewritable, in series;
a drain-side selection gate transistor that has a gate to which a drain-side selection gate line is connected and that is connected between one end of the NAND string and the bit line;
a source-side selection gate transistor that has a gate to which a source-side selection gate line is connected and that is connected between the other end of the NAND string and the source line;
a row decoder that selects the memory cell by controlling voltages applied to control gates of the memory cells and that controls voltages applied to the drain-side selection gate line and the source-side selection gate line; and
a bit line control circuit that controls a voltage of the bit line,
wherein the row decoder applies a first voltage to the control gate of a first memory cell, which is adjacent to the drain-side selection gate transistor, of the NAND string in a write operation, the first voltage being set lower than that applied to the control gates of other memory cells so as to cut off the other memory cells of the NAND string from the drain-side selection gate transistor, and
the row decoder applies a second voltage to the control gate of a second memory cell, which is adjacent to the source-side selection gate transistor, of the NAND string in a write operation, the second voltage being set lower than that applied to the control gates of the other memory cells so as to cut off the other memory cells of the NAND string from the source-side selection gate transistor.

16. The NAND-type flash memory according to claim 15, wherein the row decoder applies a third voltage to the control gate of a third memory cell, which is adjacent to the first memory cell, of the NAND string in the write operation, the third voltage being set lower than a fourth voltage applied to the control gate of a fourth memory cell other than the first memory cell, which is adjacent to the third memory cell, of the NAND string, and the third voltage being set higher than the first voltage.

17. The NAND-type flash memory according to claim 15, wherein the first memory cell is a dummy memory cell being regulated in advance such that predetermined data does not become a writing target.

18. The NAND-type flash memory according to claim 16, wherein the first memory cell and the third memory cell are dummy memory cells being regulated in advance such that predetermined data does not become a writing target.

19. The NAND-type flash memory according to claim 16, wherein the first voltage is a ground voltage.

20. The NAND-type flash memory according to claim 16, wherein the source-side selection gate transistor and the drain-side selection gate transistor are nMOS transistors.
